(19) United States
(12) Patent Application Publication
(10) Pub. No.: US 2007/0230097 A1
(43) Pub. Date: Oct. 4, 2007

(54) Cover plate and plasma display apparatus including the same

(76) Inventor: Ik-Sang Lee, Suwon-si (KR)

Correspondence Address: Robert E. Bushnell, Suite 300, 1522 K Street, N.W., Washington, DC, 20005-1202, US

(21) Appl. No.: 11/713,003

(22) Filed: Mar. 2, 2007

(30) Foreign Application Priority Data
Mar. 15, 2006 (KR) 10-2006-0023928

(51) Int. Cl. G06F 1/16; H05K 7/00

(52) U.S. Cl. 361/681; 361/679

(57) ABSTRACT

A plasma display apparatus includes: a plasma display panel; a chassis supporting the plasma display panel by being attached to a rear portion of the plasma display panel, the chassis including sub-chassis at edges thereof; circuit units disposed on the chassis to apply electric signals for driving the plasma display panel; a plurality of signal transmission members disposed around the sub-chassis, each having an end connected to one circuit unit and another end connected to the plasma display panel, for transmitting the electric signals from the circuit unit to the plasma display panel; and at least one clip type cover plate installed on at least one of the signal transmission members to protect the signal transmission members, each of which includes a plate portion formed as a thin plate, and holder portions extending from corners of the plate portion and having clip portions on end portions of the holder portions.

### CLAIM OF PRIORITY

This application makes reference to, incorporates the same herein, and claims all benefits accruing under 35 U.S.C. §119 from an application for COVERPLATE AND PLASMA DISPLAY DEVICE COMPRISING THE SAME earlier filed in the Korean Intellectual Property Office on Mar. 15, 2006 and there duly assigned Serial No. 10-2006-0023928.

### BACKGROUND OF THE INVENTION

1. Field of the Invention

The present invention relates to a plasma display apparatus, and more particularly, to a plasma display apparatus including a clip type cover plate.

2. Description of the Related Art

Plasma display apparatuses are flat panel display apparatuses for displaying images using a gas discharge, and have advantages such as they are slim line, lightweight, and they have large screen sizes, high image quality, and wide viewing angles. In addition, the plasma display apparatuses can be fabricated so as to be large using simple processes, and thus, they are considered to be the next generation of large flat panel display apparatuses.

A holder portion on a side of the plate portion and a holder portion on the other side of the plate portion may have different lengths from each other so that the cover plate can be coupled to the sub-chassis.

The cover plate may be disposed so as to correspond to one or more signal transmission members.

A rigidity reinforcing portion which is bent outwardly may be formed on at least one side of the plate portion.

The sub-chassis may be formed by upwardly bending the edge of the chassis at least once, or may be separately formed from the chassis, and coupled to the edge of the chassis using a coupling unit. The coupling unit may be a screw, a rivet, or a weld.

According to another aspect of the invention, a cover plate comprises: a plate portion formed as a thin plate; and holder portions formed so as to extend from corners of the plate portion, and having clip portions on end portions thereof.

The cover plate may be formed of copper, aluminum, or steel.

At least one of the clip portions may include a first bent portion bent toward an inner portion of the cover plate and a second bent portion bent toward an outer portion of the cover plate.

Silicon or graphite may be formed on a surface of the plate portion.

A holder portion formed on a side of the plate portion and a holder portion formed on the other side of the plate portion may have different lengths from each other.

A rigidity reinforcing portion which is bent toward the outer portion of the cover portion may be formed on at least a side of the plate portion.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is an exploded perspective view of a plasma display apparatus;

FIG. 2 is an exploded perspective view of a plasma display apparatus according to an embodiment of the present invention;

FIG. 3 is a cross-section view of a portion of the plasma display apparatus of FIG. 2, in which a cover plate is mounted on a sub-chassis;

FIG. 4 is an exploded perspective view of a plasma display apparatus according to another embodiment of the present invention;

FIG. 5 is a perspective view of a cover plate of the plasma display apparatus of FIG. 4; and

FIG. 6 is a perspective view of a modified example of the cover plate of FIG. 5.

### DETAILED DESCRIPTION OF THE INVENTION

The present invention will now be described more fully with reference to the accompanying drawings, in which exemplary embodiments of the invention are shown.

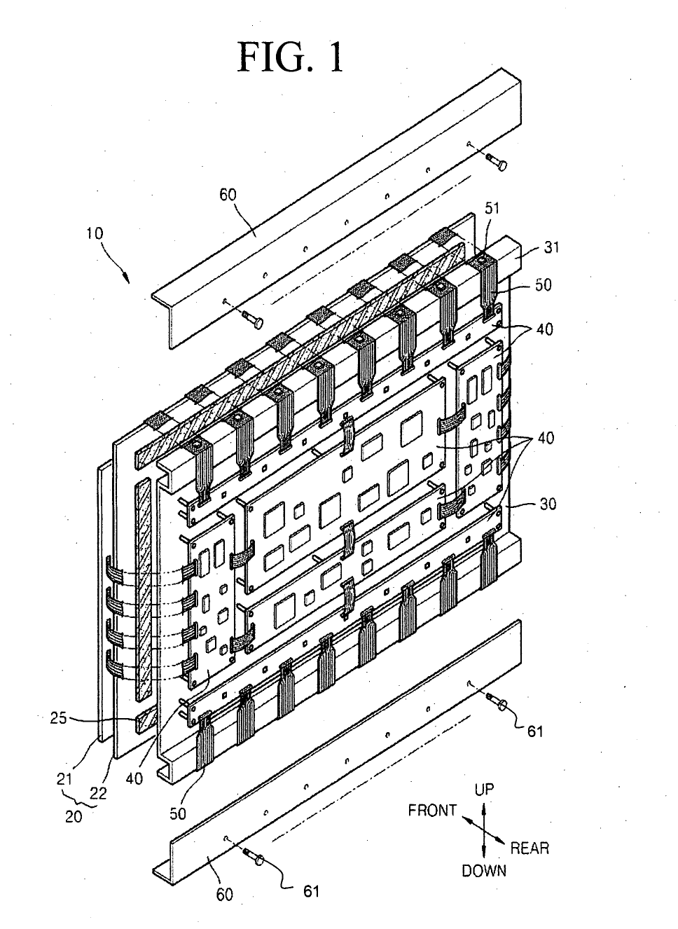

FIG. 1 is an exploded rear perspective view of a plasma display apparatus. The plasma display apparatus 10 comprises a plasma display panel 20 including a front panel 21 and a rear panel 22, strips of double-sided adhesive tape 25, a chassis 30 including a sub-chassis 31, a plurality of circuit portions 40, a plurality of signal transmission members 50 each including an integrated circuit 51, and cover plates 60.

The signal transmission members 50, which are, for example, tape carrier packages (TCP), transmit image signals to the plasma display panel 20, and generate a lot of heat during driving. In particular, the integrated circuit 51 mounted on the signal transmission members 50 generates most of the heat.

The cover plate 60 protects the signal transmission members 50, in particular, the integrated circuits 51, from external shocks, and presses the signal transmission member 50 toward the chassis 30 in order to improve heat dissipation efficiency. As shown in FIG. 1, each of the cover plates 60 may be formed as a single body having a size covering the signal transmission members 50 arranged on a side of the chassis 30. The chassis 30 and the cover plates 60 are coupled to each other using a coupling unit such as a screw 61.

However, the cover plates 60 are generally formed of aluminum in consideration of the heat dissipation efficiency, and aluminum is more expensive than other metals such as steel. Thus, when the size of cover plate 60 increases, the manufacturing cost of the plasma display apparatus increases.

In addition, a silicon pad (not shown) is generally disposed between the cover plate 60 and the integrated circuit 51 in order to prevent the integrated circuit 51 from being damaged. However, silicon has a low thermal conductivity, and thus, heat dissipation is not effectively performed.

In addition, as the cover plate 60 is coupled to the chassis 30 using a plurality of screws, the production time increases.

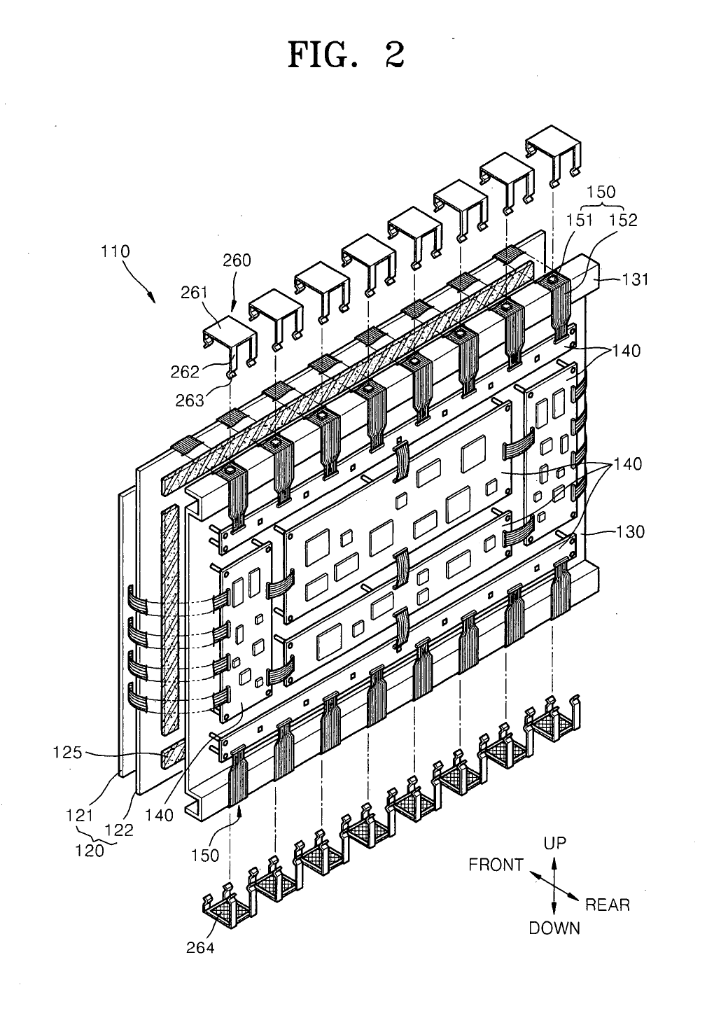

FIG. 2 is an exploded perspective view of a plasma display apparatus according to an embodiment of the present invention.

Referring to FIG. 2, the plasma display apparatus 110 according to the current embodiment includes a plasma display panel 120 and a chassis base 130. The plasma display panel 120 includes two facing substrates 121 and 122, and a plurality of electrodes (not shown) formed between the two substrates 121 and 122. A discharge gas is injected between the two substrates 121 and 122, then, a discharge voltage is applied thereto, and accordingly, the discharge gas generates ultraviolet rays. The ultraviolet rays excite, in a predetermined pattern, phosphors which are formed in the plasma display panel 120, and then, desired images can be displayed.

The plasma display panel 120 is supported by the chassis base 130 by attaching a rear portion of the plasma display panel 120 to the chassis base 130. The plasma display panel 120 and the chassis base 130 can be coupled to each other using an adhesive tape 125. Meanwhile, since the plasma display panel 120 which displays images using a discharge generates a lot of heat, a heat dissipation sheet (not shown) formed of a material having high thermal conductivity can be disposed between the chassis base 130 and the plasma display panel 120.

Sub-chassis 131 are formed on upper and lower portions of the chassis base 130, and each of the sub-chassis 131 includes three bent portions to reinforce a rigidity of the chassis base 130, and to provide a raised portion around which a plurality of signal transmission members 150 can be formed. A large part of the heat generated by the integrated circuits 151 mounted on the signal transmission members 150 is dissipated through the sub-chassis 131. The sub-chassis 131 is formed integrally with the chassis base 130, but the present invention is not limited thereto, and the sub-chassis 131 can be independently formed with respect to the chassis base 130. In this case, the sub-chassis 131 can be coupled to edges of the chassis base 130 using a coupling unit such as a screw or a rivet, or by using a welding process.

In addition, a plurality of circuit units 140, which are connected to electrodes (not shown) of the plasma display panel 120 so as to apply electric signals to the electrodes, are disposed on a rear portion of the chassis base 130. In this case, the electrodes of the plasma display panel 120 can be connected to the circuit units 140 through the signal transmission units 150, for example, tape carrier packages (TCPs).

Each of the signal transmission members 150 includes a cable portion 152, and an integrated circuit 151 mounted on the cable portion to process complex electric signals. Since the integrated circuit 151 generates a lot of heat when being driven and is sensitive to external shocks, the heat must be dissipated sufficiently and protection is required against any external shocks.

For this reason, the plasma display apparatus 110 according to the current embodiment includes a plurality of cover plates 260 for protecting the signal transmission members 150. Each cover plate 260 can be independently formed so as to correspond to one of the signal transmission members 150. For the sake of convenience, the general cover plate (such as the cover plate 60 of FIG. 1) will be referred to as a single unit cover plate, and the cover plate 260 of the current embodiment of the present invention will be referred to as an independent cover plate.

In the plasma display apparatus of FIG. 2, eight signal transmission members 150 are disposed on each of the upper and lower portions of the chassis 130, and thus eight cover plates 260 are disposed on the upper portion and eight cover plates 260 are disposed on the lower portion of the chassis 130. However, the present invention is not limited thereto, the number of signal transmission members 150 can vary, and the number of cover plates 260 does not need to be equal to the number of the signal transmission members 150. In addition, there may be cover plates corresponding to the signal transmission members 150 disposed on sides of the chassis base 130, and the cover plates 260 may not correspond to all of the signal transmission members 150 disposed on the upper or lower portion of the chassis base 130. The arrangement of the cover plates 260 and the number of the cover plates 260 can be determined according to the heat generation of the signal transmission members 150, in particular, the heat generation amount of the integrated circuits, and according to design conditions such as desirable degree of stability and fabrication costs.

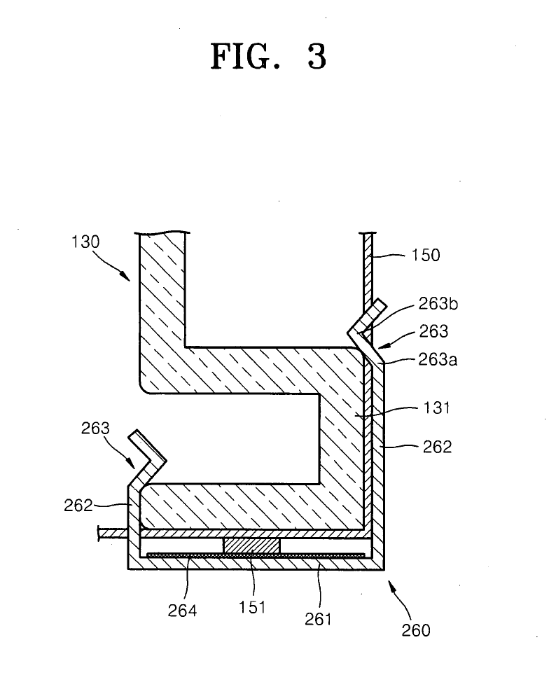

The shape of the cover plate 260 and a coupling structure between the cover plate 260 and the chassis 130 will be described in detail with reference to FIGS. 2 and 3.

FIG. 3 is a cross-section view of a portion of the plasma display apparatus of FIG. 2, in which a cover plate is mounted on a sub-chassis.

More specifically, FIG. 3 is a cross-section view of the signal transmission member 150 passing around the lower portion of the chassis 130 of FIG. 2, and the cover plate 260 coupled to the signal transmission member 150.

The cover plate 260 includes a plate portion 261, holder portions 262, and clip portions 263. The cover plate 260 can comprise copper, aluminum, or steel. The above materials have high thermal conductivity, and steel may be used to form the cover plate 260 because of its low price. In a plasma display apparatus according to the current embodiment, since the cover plate 260 is smaller than the single unit cover plate, the manufacturing cost of the cover plate 260 can be greatly reduced. In addition, if the steel is used to form the cover plate 260, the cost can be reduced even more.

The plate portion 261 presses the integrated circuit 151, and is formed as a thin rectangular plate. The cover plate 260 is coupled to the sub-chassis 131 when the clip portion 263 is clipped onto the sub-chassis 131. At least one of the clip portions 263 includes a first bent portion 263a bent toward the inside of the cover plate 260, and a second bent portion 263b bent toward the outside of the cover plate 260. The signal transmission member 150 passes between the cover plate 260 and the sub-chassis 131. According to the above coupling structure using the clip portions 263, the signal transmission member 150, in particular, the integrated circuit 151, can be firmly attached to the sub-chassis 131.

It is important to firmly attach the sub-chassis 131 and the integrated circuit 151 to each other in order to ensure good and sufficient heat dissipation. The clip type cover plate 260 can ensure sufficient heat dissipation. According to the clip type coupling process, the time for coupling the cover plate to the chassis base can be much shorter than the coupling time when using a screw for the single unit cover plate.

In addition, since the plate portion 261, which is formed of a hard material, is firmly attached to the integrated circuit 151, a buffering material 264 is attached onto the plate portion 261 in order to prevent damage to integrated circuit 151. The buffering material 264 can be formed of a graphite or a silicon material, preferably, graphite having a superior heat dissipation property. However, the material forming the buffering material is not limited to the above example, and other materials having high buffering and heat dissipation properties can be used.

The independent cover plate according to the current embodiment can reduce noise. The single unit cover plate has larger area and greater weight than the independent cover plate, and furthermore, the noise generated by the integrated circuit may be transferred to the cover plate so as to generate a resonance because a vibration frequency of the integrated circuit and a resonance frequency of the single unit cover plate are similar to each other. However, when the independent cover plate is used, there is a large difference between the vibration frequency of the integrated circuit and the resonance frequency of the independent cover plate, and thus, noise generated during the driving of the circuit can be reduced greatly.

In addition, in the cover plate 260, the holder portion 262 on one side of the plate portion 261 and the holder portion 262 on the other side of the plate portion 261 have different lengths. The lengths of the holder portion 262 are different according to the shape of the sub-chassis 131 so that the clip portion 263 can engage precisely with the corner of the sub-chassis 131. Therefore, the present invention is not limited to the above example, and the lengths of the holder portion can be formed differently from the above example.

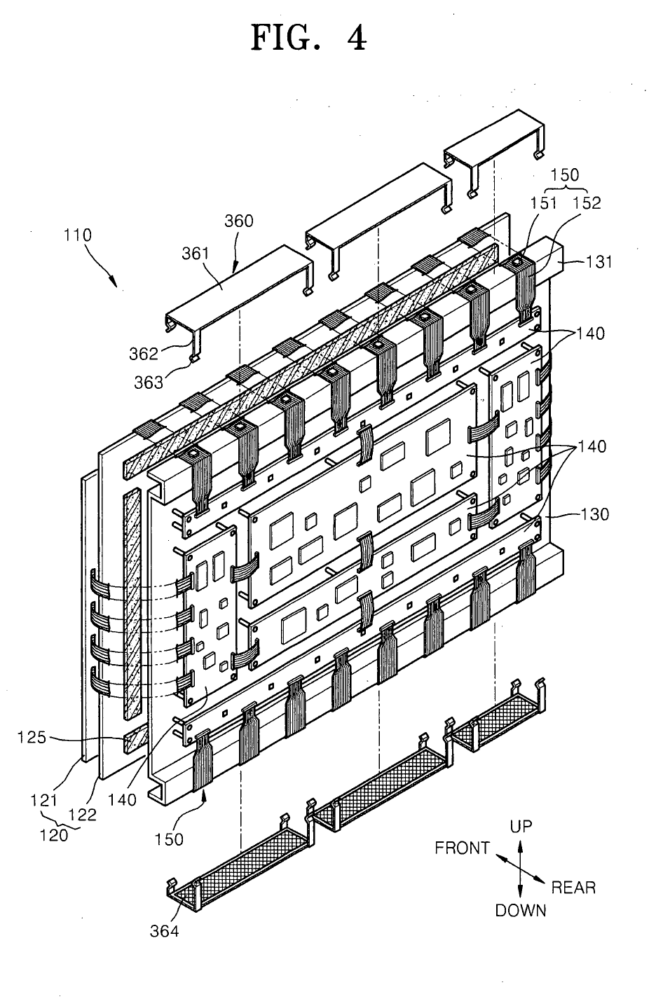

FIG. 4 is an exploded perspective view of a plasma display apparatus according to another embodiment of the present invention.

In FIG. 4, the same reference numerals as those of FIG. 1 denote the same elements. Therefore, descriptions of the same elements as those of the previous embodiment will be omitted. The cover plate, which is different from that of the previous embodiment, will be described in detail.

Comparing the plasma display apparatuses of FIG. 1 and FIG. 4, the coverplate 360 of the current embodiment of FIG. 4 is elongated so as to correspond to two or three signal transmission members 150, not one signal transmission member 150. Therefore, the time for fabricating the cover plate according to the current embodiment is reduced.

The number of signal transmission members 150 covered by one cover plate 360 is not limited. The number of signal transmission members 150 can be dependent on other conditions, such as the size of the plasma display apparatus and the number of signal transmission members 150 disposed on one side of the chassis 130.

Although the cover plate is denoted by the reference numeral 360, two kinds of cover plates are used in the current embodiment. Since eight signal transmission members 150 are disposed on the side of the chassis 130, a cover plate covering three signal transmission members 150 and a cover plate covering two signal transmission members 150 are used in the plasma display apparatus according to the current embodiment.

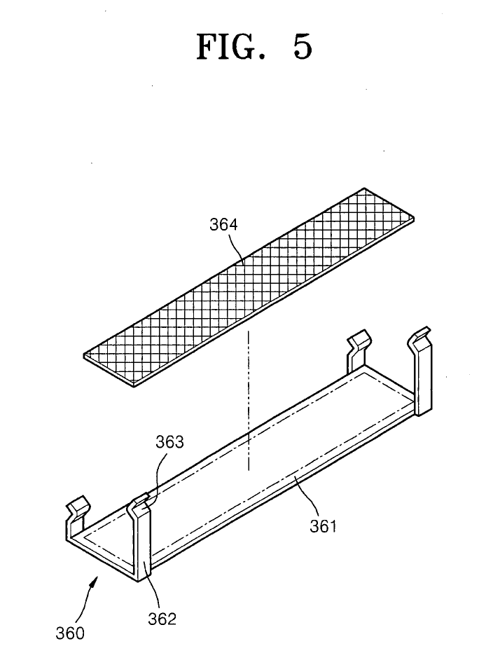

FIG. 5 is a perspective view of the cover plate of FIG. 4. As described above, the cover plate 360 includes the buffering material 364 for preventing the integrated circuit from being damaged, and for improving heat dissipation efficiency. However, the size of the cover plate 360 is not necessarily equal to the size of the plate portion 361, and is large enough for the integrated circuit to be covered by the cover plate 360.

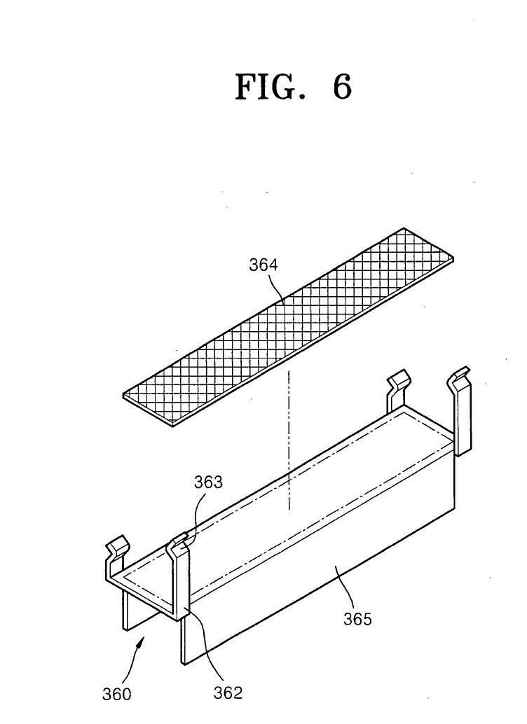

FIG. 6 is a perspective view of a modified example of the cover plate of FIG. 5. In this embodiment of the present invention, the cover plate further includes a rigidity reinforcing portion 365. Other elements are the same as those of the previous embodiment, and thus, the same reference numerals are used. When the rigidity reinforcing portion 365 is further formed, the rigidity of the cover plate 360 which is formed as a thin plate is reinforced, and vibrations transmitted from the integrated circuit are absorbed. Moreover, when the rigidity reinforcing portion 365 is formed, the heat dissipating area is increased, and thus, the heat dissipation efficiency is improved.

According to the plasma display apparatus of the present invention, since a single unit cover plate is replaced by a plurality of independent cover plates, each of which is formed as a thin plate, fabricating cost of the elements is reduced.

In addition, since the clip type cover plate is used, the time for assembling the plasma display apparatus is reduced.

While the present invention has been particularly shown and described with reference to exemplary embodiments thereof, it will be understood by those of ordinary skill in the art that various changes in form and detail may be made therein without departing from the spirit and scope of the present invention as defined by the following claims.

What is claimed is:

1. A plasma display apparatus, comprising:
a plasma display panel;
a chassis supporting the plasma display panel and attached to a rear portion of the plasma display panel, said chassis including a sub-chassis at edges thereof;
circuit units disposed on the chassis for applying electric signals for driving the plasma display panel;
a plurality of signal transmission members disposed around the sub-chassis, each signal transmission member having an end connected to one of the circuit units and another end connected to the plasma display panel, and said signal transmission members transmitting electric signals from the circuit units to the plasma display panel; and
at least one cover plate installed on at least one of the signal transmission members for protecting said at least one of the signal transmission members, each said at least one cover plate including a plate portion formed as a thin plate and holder portions extending from corners of the plate portion and having clip portions located on ends of the holder portions.

2. The plasma display apparatus of claim 1, wherein said each signal transmission member comprises a tape carrier package (TCP).

3. The plasma display apparatus of claim 1, wherein said each signal transmission member includes a cable portion and an integrated circuit mounted on the cable portion; and
wherein the plate portion of said at least one cover plate is disposed so as to press the integrated circuit, whereby the integrated circuit is firmly attached to the sub-chassis.

4. The plasma display apparatus of claim 1, wherein at least one of the clip portions includes a first bent portion which is bent toward an inner portion of said at least one cover plate, and a second bent portion which is bent toward an outer portion of said at least one cover plate.

5. The plasma display apparatus of claim 1, wherein one of silicon and graphite is formed on a surface of the plate portion.

6. The plasma display apparatus of claim 1, wherein said clip portions are engaged with the sub-chassis so that said at least one cover plate is coupled to the sub-chassis, and said each signal transmission member is disposed between said at least one cover plate and the sub-chassis, and is pressed by said at least one cover plate so as to be firmly attached to the sub-chassis.

7. The plasma display apparatus of claim 1, wherein a holder portion on a side of the plate portion and a holder portion on another side of the plate portion have different lengths with respect to each other, whereby said at least one cover plate is coupled to the sub-chassis.

8. The plasma display apparatus of claim 1, wherein said at least one cover plate is disposed so as to correspond to said at least one of the signal transmission members.

9. The plasma display apparatus of claim 1, wherein a rigidity reinforcing portion which is bent outwardly is formed on at least one side of the plate portion.

10. The plasma display apparatus of claim 1, wherein the sub-chassis is formed by upwardly bending an edge of the chassis at least once.

11. The plasma display apparatus of claim 1, wherein the sub-chassis is separately formed from the chassis, and is coupled to an the edge of the chassis using a coupling unit.

12. The plasma display apparatus of claim 11, wherein the coupling unit comprises one of a screw, a rivet and a weld.

13. A cover plate, comprising:
a plate portion formed as a thin plate; and
holder portions extending from corners of the plate portion, and having clip portions located on end portions of the holder portions.

14. The cover plate of claim 13, wherein the cover plate is formed of one of copper, aluminum and steel.

15. The cover plate of claim 13, wherein said plate portion includes a cover plate, and at least one of the clip portions includes a first bent portion bent toward an inner portion of the cover plate and a second bent portion bent toward an outer portion of the cover plate.

16. The cover plate of claim 13, wherein one of silicon and graphite is formed on a surface of the plate portion.

17. The cover plate of claim 13, wherein a holder portion formed on a side of the plate portion and a holder portion formed on another side of the plate portion have different lengths with respect to each other.

18. The cover plate of claim 13, wherein a rigidity reinforcing portion which is bent toward an outer portion of a cover portion is formed on at least a side of the plate portion.
